(19) United States
(12) Patent Application Publication
(10) Pub. No.: US 2026/0293407 A1
(43) Pub. Date: Sep. 24, 2026

(54) DISPLAY APPARATUS HAVING A DISPLAY PANEL AND OPTICAL LENSES

(71) Applicant: LG Display Co., Ltd., Seoul (KR)

(72) Inventors: You Yong JIN, Paju-si (KR); Dae Heung LEE, Paju-si (KR); Young Bok LEE, Paju-si (KR); Se Wan OH, Paju-si (KR); Go Eun KIM, Paju-si (KR)

(21) Appl. No.: 19/445,601

(22) Filed: Jan. 11, 2026

(30) Foreign Application Priority Data
Mar. 19, 2025 (KR) 10-2025-0035255

(51) Int. Cl. H10H 29/855; G06F 3/044; H10H 29/34

(52) U.S. Cl. CPC H10H 29/855; G06F 3/0446; H10H 29/34

(57) ABSTRACT

A display apparatus including optical lenses on a display panel. The display panel includes a first pixel area and a second pixel area, each including sub-pixels displaying different colors. Each of the sub-pixels include two emission areas disposed side-by-side in a first direction. The two emission areas in each sub-pixel overlap with one of the optical lenses. Each of the optical lenses has a semicircular cross-sectional shape. The second pixel area is disposed side-by-side with the first pixel area in a second direction perpendicular to the first direction. The arrangement of the sub-pixels in the second pixel is symmetrical to the arrangement of the sub-pixels in the first pixel area with respect to the second direction.

### CROSS REFERENCE TO RELATED APPLICATION

This application claims priority from and the benefit of Korean Patent Application No. 10-2025-0035255, filed on Mar. 19, 2025, which is hereby incorporated by reference for all purposes as if fully set forth herein.

### BACKGROUND

### FIELD

Embodiments of the invention relate generally to a display apparatus in which optical lenses are disposed side-by-side on a display panel.

### DISCUSSION OF THE BACKGROUND

Generally, a display apparatus provides an image to a user. For example, the display apparatus may include a display panel. The display panel may generate the image provided to the user. For example, the display panel may include light-emitting devices on emission areas of a device substrate. Each of the light-emitting devices may emit light displaying a specific color. For example, each of the light-emitting devices may include a light-emitting unit disposed between a first electrode and a second electrode.

Optical lenses may be disposed side-by-side on the display panel. For example, the light emitted from the light-emitting devices may be focused by the optical lenses. Each of the optical lenses may function as a convex lens. For example, each of the optical lenses may have a cross-section of convex shape in a direction opposite to the device substrate. Thus, in the display apparatus, the quality of the image may be improved.

The above information disclosed in this Background section is only for understanding of the background of the inventive concepts, and, therefore, it may contain information that does not constitute prior art.

### SUMMARY

A display apparatus according to one or more embodiments of the invention is capable of improving the quality of the image provided to the user disposed obliquely on the display panel.

Additional features of the inventive concepts will be set forth in the description which follows, and in part will be apparent from the description, or may be learned by practice of the inventive concepts.

According to one or more embodiments of the invention, a display panel includes: a first pixel area and a second pixel area; sub-pixels displaying different colors disposed in each of the first pixel area and the second pixel area; and optical lenses disposed on the display panel, each of the optical lenses having a semicircular cross-sectional shape in a first direction. Each of the sub-pixels includes two emission areas disposed side-by-side in the first direction and overlapping with one of the optical lenses. The second pixel area is disposed side-by-side with the first pixel area in a second direction perpendicular to the first direction. The arrangement of the sub-pixels in the second pixel area is symmetrical with the arrangement of the sub-pixels in the first pixel area.

The two emission areas in each sub-pixel may have a planar shape of a bar extending in the second direction.

The sub-pixels may include a first sub-pixel, a second sub-pixel, and a third sub-pixel. The second sub-pixel may be disposed side-by-side with the first sub-pixel in the second direction. The third sub-pixel may be spaced apart from the first sub-pixel and the second sub-pixel in the first direction. Each of the emission areas in the third sub-pixel may include a region facing the emission areas of the first sub-pixel in the first direction and a region facing the emission areas of the second sub-pixel in the first direction.

Each of the optical lenses may extend in the second direction. The emission areas of the third sub-pixel in the second pixel area may overlap with the same optical lens as the emission areas of the first sub-pixel in the first pixel area and the emission areas of the second sub-pixel in the first pixel area. The emission areas of the first sub-pixel in the second pixel area and the emission areas of the second sub-pixel in the second pixel area may overlap with the same optical lens as the emission areas of the third sub-pixel in the first pixel area.

The two emission areas disposed in each of the sub-pixels may have the same size.

A distance between adjacent emission areas in the second direction may be less than a length of each of the emission areas in the second direction.

An upper barrier pattern may be disposed between the display panel and the optical lenses. The upper barrier pattern may include upper openings. Each of the upper openings may overlap with one of the optical lenses.

A plane of each of the upper openings may have a symmetrical shape with respect to a virtual center line passing through a lens center point of the corresponding optical lens in the second direction.

A lower barrier pattern may be disposed between the display panel and the upper barrier pattern. The lower barrier pattern may include lower openings. Each of the lower openings may overlap with the upper openings of the upper barrier pattern.

The lower barrier pattern may include a different material from the upper barrier pattern.

Each of the upper openings may have a smaller size than each optical lens. A size of each of the lower openings may be larger than a size of each of the upper openings.

Each of the two emission areas in each sub-pixel may include a region overlapping with one of the optical lenses and a region disposed outside the optical lenses.

The two emission areas in each sub-pixel may display the same color.

A lens passivation layer may be disposed below the optical lenses and covering the upper barrier pattern.

The display apparatus may include a touch sensor including touch electrodes disposed between the display panel and the optical lenses in which the touch electrodes include upper openings overlapping with the optical lenses.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts

FIG. 1 is a view schematically showing a location where a display apparatus according to an embodiment of the invention is installed.

FIG. 2 is a view schematically showing the display apparatus according to an embodiment of the invention.

FIG. 3 is an enlarged view of the “K region” illustrated in FIG. 2.

FIG. 4 is a cross-sectional view taken along I-I’ of FIG. 3.

FIG. 5 is an equivalent circuit showing a driving circuit of a sub-pixel in a display panel of the display apparatus according to an embodiment of the invention.

FIG. 6 is a graph showing a relative luminance according to a viewing angle of the light emitted from a first emission area of each sub-pixel and the light emitted from a second emission area of each sub-pixel in the display apparatus according to an embodiment of the invention.

FIGS. 7, 8, 9 and 10 are views showing the display apparatus according to another embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” may encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

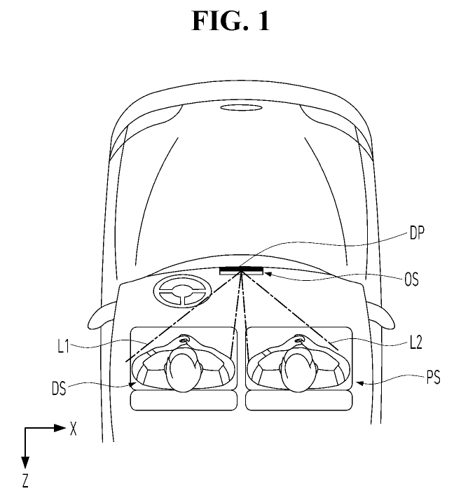

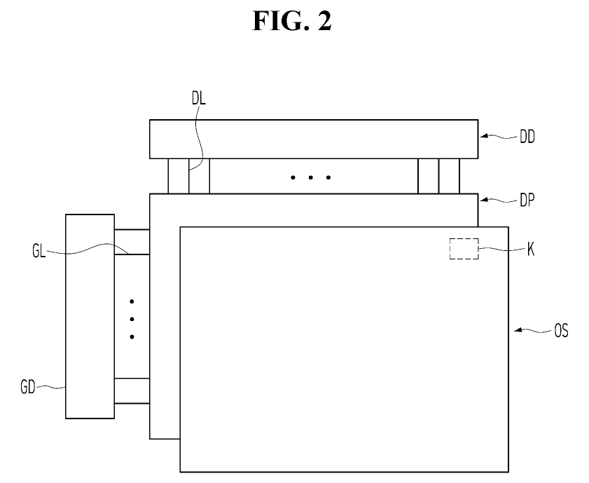

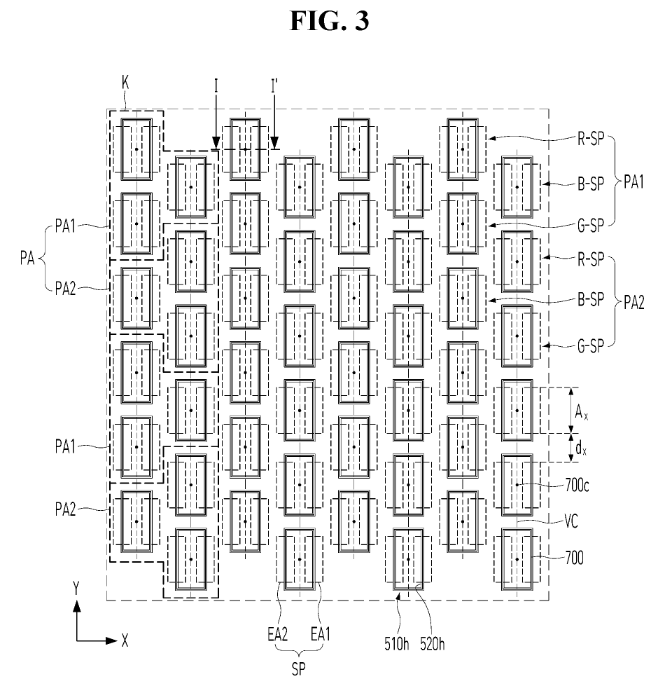

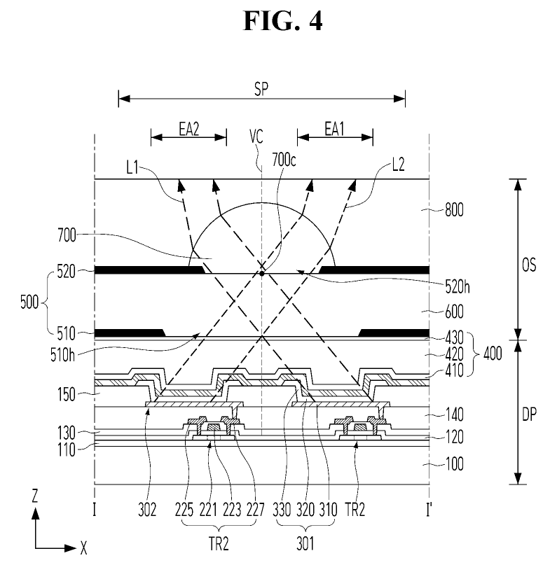

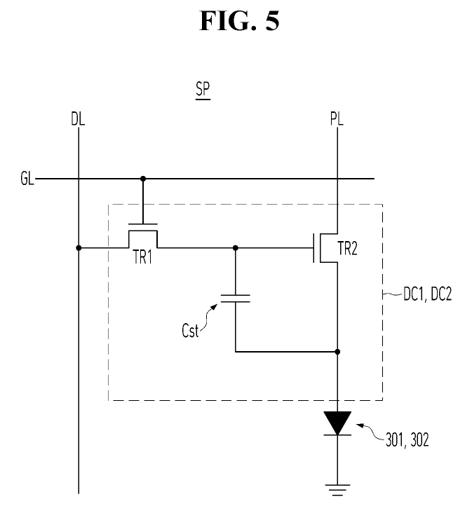

FIG. 1 is a view schematically showing a location where a display apparatus according to an embodiment of the invention is installed. FIG. 2 is a view schematically showing the display apparatus according to an embodiment of the invention. FIG. 3 is an enlarged view of the “K region” in FIG. 2. FIG. 4 is a cross-sectional view taken along I-I’ of FIG. 3. FIG. 5 is an equivalent circuit showing a driving circuit of a sub-pixel in a display panel of the display apparatus according to an embodiment of the invention.

Referring to FIGS. 1-5, the display apparatus according to an embodiment of the invention may include a display panel DP that may be installed in a car. The display panel DP may provide an image to a driver sitting in a driver seat DS and/or a passenger sitting in a passenger seat PS. For example, the display panel DP may be disposed between the driver seat DS and the passenger seat PS. The driver sitting in the driver seat DS and the passenger sitting in the passenger seat PS may be disposed in a direction inclined to a front of the display panel DP.

The display panel DP may provide the passenger sitting in the passenger seat PS with an image different from the driver sitting in the driver seat DS. For example, the display panel DP may provide a first image containing information necessary for the operation of the car to the driver sitting in the driver seat DS and a second image containing information unrelated to the operation of the car to the passenger sitting in the passenger seat PS.

The second image may be provided simultaneously with the first image. For example, a first light L1 for generating the first image and a second light L2 for generating the second image may be emitted simultaneously from the display panel DP. The first light L1 cannot be recognized by the passenger sitting in the passenger seat PS. The second light L2 cannot be recognized by the driver sitting in the driver seat DS. Thus, in the display apparatus according to an embodiment of the invention, the visibility of the first image and the visibility of the second image may be improved. In the display apparatus according to an embodiment of the invention, gaze dispersion of the driver due to the second image may be prevented. Therefore, in the display apparatus according to an embodiment of the invention, the accidents due to gaze dispersion of the driver while driving the car may be reduced.

A plurality of pixel areas PA may be disposed within the display panel DP. Each of the pixel areas PA may display various colors. For example, each of the pixel areas PA may include sub-pixels SP. Each of the sub-pixels may display a specific color. The sub-pixels of each pixel area PA may display different colors. For example, each of the pixel areas PA may include a red sub-pixel R-SP realizing a red color, a green sub-pixel G-SP realizing a green color, and a blue sub-pixel B-SP realizing a blue color.

Two emission areas may be defined in each sub-pixel SP. For example, each of the sub-pixels SP may include a first emission area EA1 and a second emission area EA2. The first emission area EA1 of each sub-pixel SP may emit the first light L1 for generating the first image provided to the driver sitting in the driver seat DS. The second emission area EA2 of each sub-pixel SP may emit the second light L2 for generating the second image provided to the passenger sitting in the passenger seat PS.

The second emission area EA2 of each sub-pixel SP may be disposed side-by-side with the first emission area EA1 of the corresponding sub-pixel SP in a first direction X. Herein, the first direction X may be defined as a direction between the driver seat DS and the passenger seat PS. A front windshield of the car may be disposed side-by-side with the display panel in a second direction Y perpendicular to the first direction X. For example, a third direction Z perpendicular to the first direction X and the second direction Y may be a front direction of the display panel DP.

As shown in FIG. 4, each of the sub-pixels SP may include a first light-emitting device 301 overlapping with the first emission area EA1 and a second light-emitting device 302 overlapping with the second emission area EA2. Each of the first light-emitting device 301 and the second light-emitting device 302 in each sub-pixel SP may generate and emit light. For example, the first light L1 may be generated by the first light-emitting device 301 of each sub-pixel SP, and the second light L2 may be generated by the second light-emitting device 302 of each sub-pixel SP. The second light-emitting device 302 of each sub-pixel SP may have a same stacked structure as the first light-emitting device 301 of the corresponding sub-pixel SP. For example, each of the first light-emitting device 301 and the second light-emitting device 302 in each sub-pixel SP may include a light-emitting unit 320 disposed between a first electrode 310 and a second electrode 330.

The light-emitting unit 320 may generate light having luminance corresponding to a voltage difference between the first electrode 310 and the second electrode 330. For example, the light-emitting unit 320 may include at least one emission material layer (EML). The emission material layer may include at least one of an organic emission material, an inorganic emission material, and a hybrid emission material. The light-emitting unit 320 may have a multi-layer structure. For example, the light-emitting unit 320 may further include at least one of a hole injection layer (HIL), a hole transport layer (HTL), an electron transport layer (ETL), and an electron injection layer (EIL).

The first electrode 310 and the second electrode 330 may include a conductive material. The second electrode 330 may include a different material from the first electrode 310. For example, the second electrode 330 may have a higher transmittance than the first electrode 310. A reflectance of the first electrode 310 may be higher than a reflectance of the second electrode 330. For example, the first electrode 310 may be a reflective electrode including metal, such as aluminum (Al) and silver (Ag), and the second electrode 330 may be a transparent electrode made of a transparent conductive material, such as ITO and IZO. Thus, in the display apparatus according to an embodiment of the invention, the light generated by the light-emitting unit 320 may be emitted through the second electrode 330.

The second light L2 emitted from the second light-emitting device 302 of each sub-pixel SP may display a same color as the first light L1 emitted from the first light-emitting device 301 of the corresponding sub-pixel SP. For example, the light-emitting unit 320 of the second light-emitting device 302 in each sub-pixel may include a same emission material layer as the light-emitting unit 320 of the second light-emitting device 302 in the corresponding sub-pixel SP. The light-emitting unit 320 of the second light-emitting device 302 in each sub-pixel SP may be formed simultaneously with the light-emitting unit 320 of the first light-emitting device 301 in the corresponding sub-pixel SP.

The second light-emitting device 302 of each sub-pixel SP may be independently controlled from the first light-emitting device 301 of the corresponding sub-pixel SP. For example, a first driving circuit DC1 electrically connected to the first light-emitting device 301 and a second driving circuit DC2 electrically connected to the second light-emitting device 302 may be disposed within each sub-pixel SP. The second driving circuit DC2 of each sub-pixel SP may be insulated from the first driving circuit DC1 of the corresponding sub-pixel SP. For example, each of the first driving circuit DC1 and the second driving circuit DC2 in each sub-pixel SP may be electrically connected to signal wirings GL, DL and PL.

The signal wirings GL, DL and PL may include a gate line GL, a data line DL, and a power voltage supply line PL. The gate line GL may be electrically connected to a gate driver GD. For example, the gate driver GD may apply a gate signal through the gate line GL. The data line DL may be electrically connected to a data driver DD. For example, the data driver DD may apply a data signal through the data line DL. A power voltage may be applied to the first driving circuit DC1 and the second driving circuit DC2 of each sub-pixel SP through the power voltage supply line PL. For example, the first driving circuit DC1 and the second driving circuit DC2 of each sub-pixel SP may generate a driving current corresponding to the data signal according to the gate signal by using the power voltage. The second driving circuit DC2 of each sub-pixel SP may have a same structure as the first driving circuit DC1 of the corresponding sub-pixel SP. For example, each of the first driving circuit DC1 and the second driving circuit DC2 in each sub-pixel SP may include a first thin film transistor TR1, a second thin film transistor TR2, and a storage capacitor Cst.

The first thin film transistor TR1 may transmit the data signal to the second thin film transistor TR2 according to the gate signal. For example, the first thin film transistor TR1 may function as a switching thin film transistor. The first thin film transistor TR1 may include a first semiconductor pattern, a first gate electrode, a first drain electrode and a first source electrode. For example, the first gate electrode may be electrically connected to the gate line GL, and the first drain electrode may be electrically connected to the data line DL. The first semiconductor pattern may include a first drain region electrically connected to the first drain electrode, a first source region electrically connected to the first source electrode, and a first channel region disposed between the first drain region and the first source region. The first source electrode may be electrically connected to the first drain electrode through the first channel region of the first semiconductor pattern according to a signal applied to the first gate electrode.

The second thin film transistor TR2 may generate the driving current according to the data signal using the power voltage. For example, the second thin film transistor TR2 may function as a driving thin film transistor. The second thin film transistor TR2 may include a second semiconductor pattern 221, a second gate electrode 223, a second drain electrode 225, and a second source electrode 227. For example, the second gate electrode 223 may be electrically connected to the first source electrode, and the second drain electrode 225 may be electrically connected to the power voltage supply line PL. The second semiconductor pattern 221 may include a second drain region electrically connected to the second drain electrode 225, a second source region electrically connected to the second source electrode 227, and a second channel region disposed between the second drain region and the second source region. The second channel region of the second semiconductor pattern 221 may have an electrical conductivity corresponding to a voltage of a signal applied to the second gate electrode 230.

An operation of the second thin film transistor TR2 may be maintained for one frame by the storage capacitor Cst. For example, the storage capacitor Cst may maintain a voltage of a signal applied to the second gate electrode 223 for one frame. The storage capacitor Cst may have a stacked structure of capacitor electrodes. For example, the storage capacitor Cst may have a structure in which a first capacitor electrode electrically connected to the second gate electrode 223 and a second capacitor electrode electrically connected to the second source electrode 227 are stacked.

The display panel DP may include a device substrate 100 supporting the first driving circuit DC1 and the second driving circuit DC2 of each sub-pixel SP. For example, the first driving circuit DC1 and the second driving circuit DC2 of each sub-pixel SP may be disposed on an upper surface of the device substrate 100. The device substrate 100 may include an insulating material. For example, the device substrate 100 may include glass or plastic. At least one of insulating layers 110, 120, 130, 140 and 150 for preventing unintended electrical connection may be disposed on the upper surface of the device substrate 100. For example, a buffer insulating layer 110, a gate insulating layer 120, an interlayer insulating layer 130, a device planarization layer 140, and a bank insulating layer 150 may be disposed on the upper surface of the device substrate 100.

The buffer insulating layer 110 may be disposed close to the device substrate 100. For example, the buffer insulating layer 110 may be in direct contact with the upper surface of the device substrate 100. The gate insulating layer 120 may be disposed on the buffer insulating layer 110. For example, the second semiconductor patterns 221 of each sub-pixel SP may be disposed between the buffer insulating layer 110 and the gate insulating layer 120. The interlayer insulating layer 130 may be disposed on the gate insulating layer 120. For example, the second gate electrodes 223 of each sub-pixel SP may be disposed between the gate insulating layer 120 and the interlayer insulating layer 130. The device planarization layer 140 may be disposed on the interlayer insulating layer 130. For example, the second drain electrodes 225 and the second source electrodes 227 of each sub-pixel SP may be disposed between the interlayer insulating layer 130 and the device planarization layer 140.

The buffer insulating layer 110, the gate insulating layer 120, the interlayer insulating layer 130, and the device planarization layer 140 may include an insulating material. The device planarization layer 140 may have a higher fluidity than the buffer insulating layer 110, the gate insulating layer 120, and the interlayer insulating layer 130. For example, the buffer insulating layer 110, the gate insulating layer 120, and the interlayer insulating layer 130 may be an inorganic insulating layer made of an inorganic insulating material, and the device planarization layer 140 may be an organic insulating layer made of an organic insulating material. A thickness difference due to the first driving circuit DC1 and the second driving circuit DC2 of each sub-pixel SP may be removed by the device planarization layer 140. For example, an upper surface of the device planarization layer 140 opposite to the device substrate 100 may be flat.

The bank insulating layer 150 may be disposed on the device planarization layer 140. The bank insulating layer 150 may define the first emission area EA1 and the second emission area EA2 in each sub-pixel SP. For example, a portion of the upper surface of the device planarization layer 140 overlapping with the first emission area EA1 of each sub-pixel SP and a portion of the upper surface of the device planarization layer 140 overlapping with the second emission area EA2 of each sub-pixel SP may be exposed by the bank insulating layer 150. The first light-emitting device 301 of each sub-pixel SP may be disposed on a portion of the upper surface of the device planarization 140 overlapping with the first emission area EA1 of each sub-pixel SP exposed by the bank insulating layer 150, and the second light-emitting device 302 of each sub-pixel SP may be disposed on a portion of the upper surface of the device planarization layer 140 overlapping with the second emission area EA2 of each sub-pixel SP exposed by the bank insulating layer 150. For example, the first electrode 310, the light-emitting unit 320, and the second electrode 330 of each of the first light-emitting device 301 and the second light-emitting device 302 in each sub-pixel SP may be sequentially stacked on the upper surface of the device planarization layer 140. A portion of the device substrate 100 overlapping with the bank insulating layer 150 may be defined as a non-emission region in which light is not generated.

The bank insulating layer 150 may include an insulating material. For example, the bank insulating layer 150 may be an organic insulating layer made of an organic insulating material. The first electrode 310 of the first light-emitting device 301 in each sub-pixel SP may be electrically connected to the first driving circuit DC1 of the corresponding sub-pixel SP. For example, the first electrode 310 of the first light-emitting device 301 in each sub-pixel SP may be in direct contact with the second source electrode 227 of the first driving circuit DC1 in the corresponding sub-pixel SP without being limited thereto. The first electrode 310 of the second light-emitting device 302 in each sub-pixel SP may be electrically connected to the second driving circuit DC2 of the corresponding sub-pixel SP. For example, the first electrode 310 of the second light-emitting device 302 in each sub-pixel SP may be in direct contact with the second source electrode 227 of the second driving circuit DC2 in the corresponding sub-pixel SP, without being limited thereto. The first electrode 310 of the second light-emitting device 302 in each sub-pixel SP may be insulated from the first electrode 310 of the first light-emitting device 301 in the corresponding sub-pixel SP by the bank insulating layer 150. For example, the bank insulating layer 150 may cover an edge of each of the first electrodes 310 in each sub-pixel SP.

The second emission area EA2 of each sub-pixel SP may have a same length as the first emission area EA1 of the corresponding sub-pixel SP in the first direction X. The second emission area EA2 of each sub-pixel SP may have a same length as the first emission area EA1 of the corresponding sub-pixel SP in the second direction Y. For example, the second emission area EA2 of each sub-pixel SP may have a same size as the first emission area EA1 of the corresponding sub-pixel SP. The second emission area EA2 of each sub-pixel SP may have a same planar shape as the first emission area EA1 of the corresponding sub-pixel SP. The first emission area EA1 and the second emission area EA2 of each sub-pixel SP may have a relatively great length in the second direction Y. For example, the first emission area EA1 and the second emission area EA2 of each sub-pixel SP may have a planar shape of a bar extending in the second direction Y. The second emission area EA2 of each sub-pixel SP may be spaced apart from the first emission area EA1 of the corresponding sub-pixel SP in the first direction X.

Each of the first emission area EA1 and the second emission area EA2 in each sub-pixel SP may have a same size as the first emission area EA1 and the second emission EA2 in adjacent sub-pixel SP. Each of the first emission area EA1 and the second emission area EA2 in the green sub-pixel G-SP may have a same size as the first emission area EA1 and the second emission EA2 in the red sub-pixel R-SP, and each of the first emission area EA1 and the second emission area EA2 in the blue sub-pixel B-SP may have a same size as the first emission area EA1 and the second emission EA2 in the green sub-pixel G-SP. Each of the red sub-pixel R-SP, the green sub-pixel G-SP, and the blue sub-pixel B-SP in each pixel area PA may have a same size as the red sub-pixel R-SP, the green sub-pixel G-SP, and the blue sub-pixel B-SP in adjacent pixel area PA.

The display panel DP may include an encapsulation structure 400 disposed on the first light-emitting device 301 and the second light-emitting device 302 of each sub-pixel SP. The encapsulation structure 400 may prevent damage to the first light-emitting device 301 and the second light-emitting device 302 in each sub-pixel SP due to external impact and moisture. For example, the first light-emitting device 301 and the second light-emitting device 302 of each sub-pixel SP may be completely covered by the encapsulation structure 400. The encapsulation structure 400 may include a region overlapping with the first emission area EA1 of each sub-pixel SP, a region overlapping with the second emission area EA2 of each sub-pixel SP, and a region overlapping with the non-emission area. The encapsulation structure 400 may have a multi-layer structure. For example, the encapsulation structure 400 may include a first encapsulating layer 410, a second encapsulating layer 420, and a third encapsulating layer 430, which are sequentially stacked. The first encapsulating layer 410, the second encapsulating layer 420, and the third encapsulating layer 430 may include an insulating material. The second encapsulating layer 420 may have a higher fluidity than the first encapsulating layer 410 and the third encapsulating layer 430. For example, the first encapsulating layer 410 and the third encapsulating layer 430 may be inorganic encapsulating layers made of an inorganic insulating material, and the second encapsulating layer 420 may be an organic encapsulating layer made of an organic insulating material. A thickness difference due to the first light-emitting device 301 and the second light-emitting device 302 of each sub-pixel SP may be removed by the second encapsulating layer 420. For example, an upper surface of the encapsulation structure 400 opposite to the device substrate 100 may be flat.

An optical structure OS may be disposed on the display panel DP. A travelling path of the first light L1 emitted from the first light-emitting device 301 of each sub-pixel SP and a travelling path of the second light L2 emitted from the second light-emitting device 302 of each sub-pixel SP may be adjusted by the optical structure OS. For example, the optical structure OS may include a barrier structure 500 disposed on the encapsulation structure 400 of the display panel DP. The barrier structure 500 may limit the travelling direction of the first light L1 and the second light L2 emitted from each sub-pixel SP. The barrier structure 500 may have a multi-layer structure. For example, the barrier structure 500 may have a stacked structure of a lower barrier pattern 510 and an upper barrier pattern 520.

The lower barrier pattern 510 may be disposed close to the upper surface of the encapsulation structure 400. For example, the lower barrier pattern 510 may be in direct contact with the upper surface of the encapsulation structure 400. The lower barrier pattern 510 may include a material capable to blocking light. The lower barrier pattern 510 may include a material having a low reflectance. For example, the lower barrier pattern 510 may include a black dye, such as carbon black.

The lower barrier pattern 510 may include lower openings 510h. Each of the lower openings 510hmay overlap one of the sub-pixels SP. Thus, in the display apparatus according to an embodiment of the invention, the second light L2 emitted from the second emission area EA2 of each sub-pixel SP may be pass through a same lower opening 510has the first light L1 emitted from the first emission area EA1 of the corresponding sub-pixel SP.

The lower opening 510h on each sub-pixel SP may overlap with a region disposed between the first emission area EA1 and the second emission area EA2 of the corresponding sub-pixel SP. Each of the first emission area EA1 and the second emission area EA2 in each sub-pixel SP may include a region overlapping with one of the lower openings 510h and a region disposed outside the lower openings 510h. For example, the lower opening 510hof each sub-pixel SP may overlap with a portion of the first emission area EA1 disposed close to the second emission area EA2 in the corresponding sub-pixel SP and a portion of the second emission area EA2 disposed close to the first emission area EA1 in the corresponding sub-pixel SP.

The first emission area EA1 of each sub-pixel SP may be disposed closer to the passenger seat PS than the second emission area EA2 of the corresponding sub-pixel SP. The second emission area EA2 of each sub-pixel SP may be disposed closer to the driver seat DS than the first emission area EA1 of the corresponding sub-pixel SP. Thus, in the display apparatus according to an embodiment of the invention, the first light L1 emitted from the first emission area EA1 of each sub-pixel SP may travel in a direction of the driver seat DS passing through the one of the lower openings 510h, and the second light L2 emitted from the second emission area EA2 of each sub-pixel SP may travel in a direction of the passenger seat PS passing through one of the lower openings 510h.

A portion of the first emission area EA1 and a portion of the second emission area EA2 disposed outside the lower openings 510h in each sub-pixel SP may overlap with the lower barrier pattern 510. For example, a portion of the first emission area EA1 disposed far from the second emission area EA2 in each sub-pixel SP and a portion of the second emission area EA2 disposed far from the first emission area EA1 in each sub-pixel SP may overlap with the lower barrier pattern 510. Thus, in the display apparatus according to an embodiment of the invention, light emitted toward the passenger seat PS from the first emission area EA1 of each sub-pixel SP and light emitted toward the driver seat DS from the second emission area EA2 of each sub-pixel SP may be primarily blocked by the lower barrier pattern 510.

The lower opening 510h of each sub-pixel SP may have a planar shape corresponding to the first emission area EA1 and the second emission area EA2 defined in the corresponding sub-pixel SP. For example, a plane of the lower opening 510hon each sub-pixel SP may have a bar shape extending in the second direction Y.

The upper barrier pattern 520 may be disposed on the lower barrier pattern 510. The upper barrier pattern 520 may be spaced apart from the lower barrier pattern 510. For example, the optical structure OS may include an optical insulating layer 600 covering the lower barrier pattern 510. The optical insulating layer 600 may include a transparent material. The optical insulating layer 600 may have a relatively high fluidity. For example, the optical insulating layer 600 may be an organic insulating layer made of an organic insulating material. The optical insulating layer 600 may extend on the first emission area EA1 and the second emission area EA2 of each sub-pixel SP. For example, the lower openings 510h of the lower barrier pattern 510 may be filled by the optical insulating layer 600. A thickness difference due to the lower barrier pattern 510 may be removed by the optical insulating layer 600. For example, an upper surface of the optical insulating layer 600 opposite to the display panel DP may be flat.

The first light L1 and the second light L2 passing through the lower opening 510h of each sub-pixel SP may be emitted passing thorough the optical insulating layer 600. Thus, in the display apparatus according to an embodiment of the invention, an optical distance of the first light L1 and an optical distance of the second light L2 emitted from each sub-pixel SP may be proportional to a thickness of the optical insulating layer 600. Therefore, in the display apparatus according to an embodiment of the invention, the optical distance of the first light L1 and the optical distance of the second light L2 emitted from each sub-pixel SP may be sufficiently secured by the optical insulating layer 600.

The upper barrier pattern 520 may be disposed on the upper surface of the optical insulating layer 600. The upper barrier pattern 520 may be disposed close to the upper surface of the optical insulating layer 600. For example, the upper barrier pattern 520 may be in direct contact with the upper surface of the optical insulating layer 600. The upper barrier pattern 520 may include a material capable of blocking light. For example, the upper barrier pattern 520 may include a black dye, such as carbon black. The upper barrier pattern 520 may include a same material as the lower barrier pattern 510.

The upper barrier pattern 520 may include upper openings 520h. Each of the upper openings 520h may overlap with one of the lower openings 510h. For example, the first emission EA1 and the second emission area EA2 of each sub-pixel SP may overlap with one of the upper openings 520h. Thus, in the display apparatus according to an embodiment of the invention, the second light L2 passing through the lower opening 510h of each sub-pixel SP may pass through a same upper opening 520h as the first light L1 passing through the lower opening 510h of the corresponding sub-pixel SP. Therefore, in the display apparatus according to an embodiment of the invention, the travelling direction of the first light L1 emitted from each sub-pixel SP and the travelling direction of the second light L2 emitted from each sub-pixel SP may be limited by the lower barrier pattern 510 and the upper barrier pattern 520.

A plane of the upper opening 520h on each sub-pixel SP may have a shape corresponding to a plane of the lower opening 510h disposed on the corresponding sub-pixel SP. For example, the upper opening 520h of each sub-pixel SP may have a bar shape extending in the second direction Y. The center of the upper opening 520h on each sub-pixel SP may coincide with the center of the lower opening 510hon the corresponding sub-pixel SP, in a plan view. The upper opening 520h of each sub-pixel SP may be smaller than the lower opening 510h of the corresponding sub-pixel SP. For example, the upper opening 520h of each sub-pixel SP may be disposed within the lower opening 510h of the corresponding sub-pixel SP. Thus, in the display apparatus according to an embodiment of the invention, some of the light passing through the lower opening 510h of each sub-pixel SP may be blocked by the upper barrier pattern 520.

The center of the first emission area EA1 and the center of the second emission area EA2 defined in each sub-pixel SP may be disposed within the lower opening 510h of the corresponding sub-pixel SP. The upper barrier pattern 520 may overlap with the center of the first emission area EA1 and the center of the second emission area EA2 defined in each sub-pixel SP. That is, in the display apparatus according to an embodiment of the invention, light emitted in a direction perpendicular to the upper surface of the device substrate 100 from the first emission area EA1 of each sub-pixel SP and light emitted in the direction perpendicular to the upper surface of the device substrate 100 from the second emission area EA2 of each sub-pixel SP may be blocked by the upper barrier pattern 520. Thus, in the display apparatus according to an embodiment of the invention, the first light L1 emitted from the first emission area EA1 of each sub-pixel SP cannot be recognized by the passenger sitting in the passenger seat PS, and the second light L2 emitted from the second emission area EA2 of each sub-pixel SP cannot be recognized by the driver sitting in the driver seat DS. Therefore, in the display apparatus according to an embodiment of the invention, the visibility of the first image by the first light L1 of each sub-pixel SP and the visibility of the second image by the second light L2 of each sub-pixel SP may be improved. In the display apparatus according to an embodiment of the invention, gaze dispersion of the driver due to the second image may be prevented.

The optical structure OS may include optical lenses 700 disposed on the upper barrier pattern 520. Each of the optical lenses 700 may overlap with one of the upper openings 520h. For example, the first emission area EA1 and the second emission area EA2 of each sub-pixel SP may overlap with the optical lens 700. The optical lens 700 of each sub-pixel SP may have a planar shape corresponding to the upper opening 520h of the corresponding sub-pixel SP. For example, a plane of the optical lens 700 on each sub-pixel SP may have a bar shape extending in the second direction Y.

A surface of each optical lens 700 opposite to the device substrate 100 may have a convex shape in a direction opposite to the device substrate 100. For example, a cross-section of each optical lens 700 in the first direction X may have a semicircular shape that is convex in a direction away from the device substrate 100. Thus, in the display apparatus according to an embodiment of the invention, each of the optical lenses 700 may function as a convex lens. For example, in the display apparatus according to an embodiment of the invention, the first light L1 and the second light L2 passing through the upper opening 520h of each sub-pixel SP may be focused by the optical lens 700 disposed on the corresponding sub-pixel SP. Therefore, in the display apparatus according to an embodiment of the invention, the quality of the first image by the first light L1 emitted from each sub-pixel SP and the quality of the second image by the second light L2 emitted from each sub-pixel SP may be improved.

The optical lens 700 of each sub-pixel SP may be larger than the upper opening 520hof the corresponding sub-pixel SP. For example, the upper opening 520hof each sub-pixel SP may be covered by the optical lens 700 of the corresponding sub-pixel SP. The optical lens 700 of each sub-pixel SP may be in direct contact with the upper surface of the optical insulating layer 600 within the upper opening 520h of the corresponding sub-pixel SP. An edge of the optical lens 700 on each sub-pixel SP may overlap with the upper barrier pattern 520. Thus, in the display apparatus according to an embodiment of the invention, the light extraction efficiency of the first light L1 and the second light L2 emitted from each sub-pixel SP may be improved. The optical lens 700 on each sub-pixel SP may be smaller than the lower opening 510h on the corresponding sub-pixel SP.

A lens central point 700c of the optical lens 700 on each sub-pixel SP may be coincidental with the center of the upper opening 520h on the corresponding sub-pixel SP, in a plan view. For example, a virtual center line VC passing through the lens central point 700c of each sub-pixel SP in the second direction Y may be disposed between the first emission area EA1 and the second emission area EA2 of the corresponding sub-pixel SP in the first direction X. A distance between the virtual center line VC and the second emission area EA2 of each sub-pixel SP may be the same as a distance between the first emission area EA1 and the virtual center line VC of the corresponding sub-pixel SP. For example, a plane of the upper opening 520hon each sub-pixel SP may have a symmetric shape with respect to the virtual center line VC of the corresponding sub-pixel SP. Thus, in the display apparatus according to an embodiment of the invention, the difference in the quality between the first image by the first light L1 emitted from each sub-pixel SP and the second image by the second light L2 emitted from each sub-pixel SP may be prevented.

The optical structure OS may include a lens planarization layer 800 disposed on the optical lens 700 of each sub-pixel SP. The lens planarization layer 800 may prevent damage of the optical lens 700 disposed on each sub-pixel SP due to the external impact. For example, the optical lens 700 of each sub-pixel SP may be completely covered by the lens planarization layer 800. The lens planarization layer 800 may extend on the upper surface of the upper barrier pattern 520 opposite to the device substrate 100. For example, the lens planarization layer 800 may include a region overlapping with the optical lens 700 of each sub-pixel SP and a region overlapping with the upper barrier pattern 520. The upper surface of the upper barrier pattern 520 opposite to the device substrate 100 may be in direct contact with the lens planarization layer 800. For example, the lens planarization layer 800 may be in direct contact with the surface having convex shape of each optical lens 700.

The lens planarization layer 800 may include an insulating material. For example, the lens planarization layer 800 may be an organic insulating layer made of an organic insulating material. A thickness difference due to the optical lens 700 of each sub-pixel SP may be removed by the lens planarization layer 800. For example, an upper surface of the lens planarization layer 800 opposite to the device substrate 100 may be flat. The lens planarization layer 800 may have a smaller refractive index than the optical lens 700 of each sub-pixel SP. For example, in the display apparatus according to an embodiment of the invention, the first light L1 and the second light L2 passing through the optical lens 700 of each sub-pixel SP may be focused by a difference in refractive index between the corresponding optical lens 700 and the lens planarization layer 800.

As shown in FIG. 3, the plurality of pixel areas PA of the display panel DP may include first pixel areas PA1 and second pixel areas PA2 disposed side-by-side with the first pixel areas PA1 in the second direction Y. The first pixel areas PA1 may be disposed side-by-side in the first direction X. For example, the first pixel areas PA1 and the second pixel areas PA2 may be repeatedly arranged in the second direction Y. The second pixel areas PA2 may be disposed side-by-side in the first direction X.

An arrangement of the sub-pixels SP in each second pixel area PA2 may be symmetrical to an arrangement of the sub-pixels SP in each first pixel area PA1. For example, in the display apparatus according to an embodiment of the invention, each of the first pixel areas PA1 and the second pixel areas PA2 may include the red sub-pixel R-SP, the green sub-pixel G-SP disposed side-by-side with the red sub-pixel R-SP in the second direction Y, and the blue sub-pixel B-SP spaced apart from the red sub-pixel R-SP and the green sub-pixel G-SP in the first direction X, wherein the green sub-pixel G-SP of each first pixel area PA1 may be disposed between the red sub-pixel R-SP of the corresponding first pixel area PA1 and the blue sub-pixel B-SP of one of the second pixel areas PA2 in the second direction Y, and wherein the red sub-pixel R-SP of each second pixel area PA2 may be disposed between the blue sub-pixel B-SP of one of the first pixel areas PA1 and the green sub-pixel G-SP of the corresponding second pixel area PA2. Thus, in the display apparatus according to an embodiment of the invention, the sub-pixels displaying different colors may be repeatedly arranged in the second direction Y. That is, in the display apparatus according to an embodiment of the invention, a distance between the sub-pixels SP displaying a same color in the second direction Y may be constant. Therefore, in the display apparatus according to an embodiment of the invention, the color variation due to a difference in distance between the sub-pixels SP displaying a same color in the second direction Y may be prevented.

The blue sub-pixel B-SP of each first pixel area PA1 may be alternately disposed with the red sub-pixel R-SP and the green sub-pixel G-SP of the corresponding first pixel area PA1 in the first direction X. The blue sub-pixel B-SP of each second pixel area PA2 may be alternately disposed with the red sub-pixel R-SP and the green sub-pixel G-SP of the corresponding second pixel area PA2 in the first direction X. For example, each of the sub-pixels SP may display a different color from the sub-pixels SP disposed in a direction inclined to the first direction X and the second direction Y. Thus, in the display apparatus according to an embodiment of the invention, a distance between the sub-pixels SP displaying a same color in a direction inclined to the first direction X and the second direction Y may be increased. Therefore, in the display apparatus according to an embodiment of the invention, the unintended color mixing due to a short distance between adjacent sub-pixels SP in a direction inclined to the first direction X and the second direction Y.

In the display apparatus according to an embodiment of the invention, a length of the first emission area EA1 in the second direction Y on each sub-pixel SP and a length of the second emission area EA2 in the second direction Y on each sub-pixel SP may be increased. For example, in the display apparatus according to an embodiment of the invention, each of the first emission area EA1 and the second emission area EA2 of the blue sub-pixel B-SP within each first pixel area PA1 may include a region facing the first emission area EA1 and the second emission area EA2 of the red sub-pixel R-SP in the first direction X within the corresponding first pixel area PA1, and a region facing the first emission area EA1 and the second emission area EA2 of the green sub-pixel G-SP in the first direction X within the corresponding first pixel area PA1, and each of the first emission area EA1 and the second emission area EA2 of the blue sub-pixel B-SP within each second pixel area PA2 may include a region facing the first emission area EA1 and the second emission area EA2 of the red sub-pixel R-SP in the first direction X within the corresponding second pixel area PA2 and a region facing the first emission area EA1 and the second emission area EA2 of the green sub-pixel G-SP in the first direction X within the corresponding second pixel area PA2. A distance dₓ between adjacent sub-pixel SP in the second direction Y may be less than a length Aₓ of each of the first emission area EA1 and the second emission area EA2 defined in the second direction Y within each sub-pixel SP. The first emission area EA1 and the second emission area EA2 of the green sub-pixel G-SP within each first pixel area PA1 may include a region facing the first emission area EA1 and the second emission area EA2 of the blue sub-pixel B-SP in the first direction X within the corresponding first pixel area PA1 and a region facing the first emission area EA1 and the second emission area EA2 of the red sub-pixel R-SP in the first direction X within one of the second pixel areas PA2. The first emission area EA1 and the second emission area EA2 of the red sub-pixel R-SP within each second pixel area PA2 may include a region facing the first emission area EA1 and the second emission area EA2 of the green sub-pixel G-SP in the first direction X within one of the first pixel areas PA1 and a region facing the first emission area EA1 and the second emission area EA2 of the blue sub-pixel B-SP in the first direction X within the corresponding second pixel area PA2. Thus, in the display apparatus according to an embodiment of the invention, the amount of the first light L1 emitted from the first emission area EA1 of each sub-pixel SP and the amount of the second light L2 emitted from the second emission area EA2 of each sub-pixel SP may be increased.

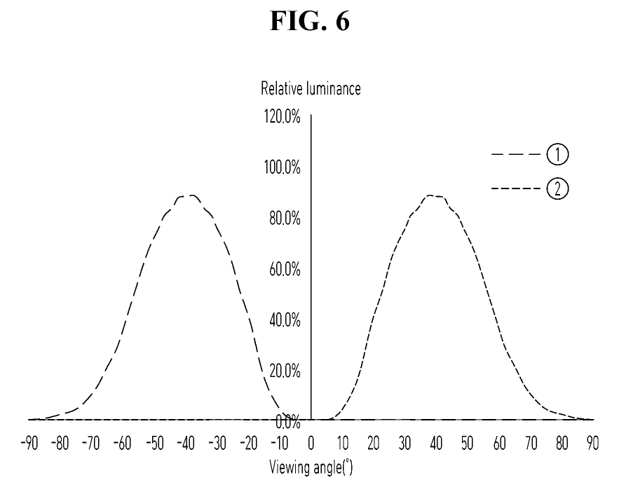

FIG. 6 is a graph showing a relative luminance ① of the first light L1 emitted from the first emission area EA1 of each sub-pixel SP according to a viewing angle and a relative luminance ② of the second light L2 emitted from the second emission area EA2 of each sub-pixel SP according to a viewing angle in the display apparatus according to an embodiment of the invention. Herein, the relative luminance ① of the first light L1 is based on the front luminance of light emitted from the first emission area EA1 of each sub-pixel SP measured in the absence of the optical structure OS, and the relative luminance ② of the second light L2 is based on the front luminance of light emitted from the second emission area EA2 of each sub-pixel SP measured in the absence of the optical structure OS..

Referring to FIG. 6, in the display apparatus according to an embodiment of the invention, the first light L1 emitted from each sub-pixel SP cannot be detected at a viewing angle of 10° to 90°, and the second light L2 emitted from each sub-pixel SP cannot be detected at a viewing angle of -90° to -10°. That is, in the display apparatus according to an embodiment of the invention, the first light L1 emitted from each sub-pixel SP cannot be recognized by the passenger sitting in the passenger seat PS, and the second light L2 emitted from each sub-pixel SP cannot be recognized by the driver sitting in the driver seat DS. Thus, in the display apparatus according to an embodiment of the invention, the visibility of the first image realized by the first light L1 of each sub-pixel SP and the visibility of the second image realized by the second light L2 of each sub-pixel may be improved. In addition, the display apparatus according to an embodiment of the invention, gaze dispersion of the driver due to the second image may be prevented.

Referring to FIG. 6, in the display apparatus according to an embodiment of the invention, the first light L1 emitted from each sub-pixel SP may have a maximum luminance at a viewing angle of -30° to -50°, and the second light L2 emitted from each sub-pixel SP may have a maximum luminance at a viewing angle of 30° to 50°. Thus, in the display apparatus according to an embodiment of the invention, the first light L1 recognized by the driver sitting in the driver seat DS may have a maximum luminance, and the second light L2 recognized by the passenger sitting in the passenger seat PS may have a maximum luminance. The maximum luminance of the first light L1 may be substantially the same as the front luminance of light emitted from the first emission area EA1 of each sub-pixel SP measured in the absence of the optical structure OS, and the maximum luminance of the second light L2 may be substantially a same as the front luminance of light emitted from the second emission area EA2 of each sub-pixel measured in the absence of the optical structure OS. Therefore, in the display apparatus according to an embodiment of the invention, the quality of the first image provided to the driver sitting in the driver seat DS by the first light L1 of each sub-pixel SP and the quality of the second image provide to the passenger sitting in the passenger seat PS by the second light L2 of each sub-pixel SP may be improved.

Accordingly, the display apparatus according to an embodiment of the invention may include the display panel DP including the first pixel areas PA1 and the second pixel areas PA2, and the optical lenses 700 disposed on the display panel DP. Each of the first pixel areas PA1 and the second pixel areas PA2 may include the sub-pixels SP displaying different colors, wherein each of the sub-pixels SP may include the first emission area EA1 and the second emission area EA2 disposed side-by-side with the first emission area PA1 in the first direction X, wherein the first emission area EA1 and the second emission area EA2 of each sub-pixel SP may overlap with one of the optical lenses 700, wherein each of the optical lenses 700 may have a semicircular cross-sectional shape in the first direction X, wherein each of the second pixel area PA2 may be disposed side-by-side one of the first pixel areas PA1 in the second direction Y, and wherein the arrangement of the sub-pixels SP within each second pixel area PA2 may be symmetrical to the arrangement of the sub-pixels SP within each first pixel area PA1 based on the second direction Y. Thus, in the display apparatus according to an embodiment of the invention, the first light L1 emitted from the first emission area EA1 of each sub-pixel SP cannot be recognized by the passenger sitting in the passenger seat PS, the second light L2 emitted from the second emission area EA2 of each sub-pixel SP cannot be recognized by the driver sitting in the driver seat DS, and the quality of the first image by the first light L1 of each sub-pixel SP and the quality of the second image by the second light L2 of each sub-pixel SP may be improved. Therefore, in the display apparatus according to an embodiment of the invention, the visibility of the first image and the visibility of the second image may be improved, and gaze dispersion of the driver due to the second image may be prevented. In addition, the display apparatus according to an embodiment of the invention, low-power operation may be possible and power consumption may be reduced, without decreasing the quality of the first image and the second image.

The display apparatus according to an embodiment of the invention is described such that each of the driving circuits DC1 and DC2 consists of the first thin film transistor TR1, the second thin film transistor TR2, and the storage capacitor Cst. However, in the display apparatus according to another embodiment of the invention, each of the driving circuits DC1 and DC2 may include a driving thin film transistor and at least one switching thin film transistor. For example, in the display apparatus according to another embodiment of the invention, each of the driving circuits DC1 and DC2 may include a third thin film transistor to initialize the storage capacitor Cst according to the gate signal. The third thin film transistor may include a third semiconductor pattern, a third gate electrode, a third drain electrode, and a third source electrode. For example, the third gate electrode may be electrically connected to the gate line GL, the third drain electrode may be electrically connected to an initial line applying a signal to the initialization of the storage capacitor Cst. The third semiconductor pattern may include a third drain region electrically connected to the third drain electrode, a third source region electrically connected to the third source electrode, and a third channel region disposed between the third drain region and the third source region. The third source electrode may be electrically connected to the third drain electrode through the third channel region of the third semiconductor pattern according to a signal applied to the third gate electrode. Thus, in the display apparatus according to another embodiment of the invention, the degree of freedom in the configuration of each driving circuit DC1 and DC2 may be improved.

In the display apparatus according to an embodiment of the invention, the location and the electric connection of the first drain electrode, the first source electrode, the second drain electrodes 225, and the second source electrode 227 in each driving circuit DC1 and DC2 may vary depending on the configuration of the corresponding driving circuit DC1 and DC2 and/or the type of the corresponding thin film transistors TR1 and TR2. For example, in the display apparatus according to another embodiment of the invention, the second gate electrode 223 may be electrically connected to the first drain electrode. Thus, in the display apparatus according to another embodiment of the invention, the degree of freedom in the configuration of each driving circuit DC1 and DC2 and the type of each thin film transistor TR1 and TR2 may be improved.

The display apparatus according to an embodiment of the invention is described such that the display panel DP is disposed only between the driver seat DS and the passenger seat PS. However, in the display apparatus according to another embodiment of the invention, the display panel DP and the optical structure OS may extend in the first direction X. For example, in the display apparatus according to another embodiment of the invention, the display panel DP and the optical structure OS may include a region disposed in front of the driver seat DS, a region disposed between the driver seat DS and the passenger seat PS, and a region disposed in front of the passenger seat PS. The display panel DP may be formed as an integrated type in which the region disposed between the driver seat DS and the passenger seat PS is continuous with the region disposed in front of the driver seat DS and the region disposed in front of the passenger seat PS. Thus, in the display apparatus according to another embodiment of the invention, the degree of freedom in the location and the shape of the display panel DP may be improved.

In the display apparatus according to another embodiment of the invention, a plurality of display panels DP may be used. For example, in the display apparatus according to another embodiment of the invention, the display panel DP may include a first display panel installed in front of the driver seat DS, a second display panel installed in front of the passenger seat PS, and a third display installed between the driver seat DS and the passenger seat PS. The first display panel, the second display panel, and the third display panel may have a same structure. The first display panel, the second display panel, and the third display panel may be separated from each other. For example, the first display panel, the second display panel, and the third display panel may realize different images. Thus, in the display apparatus according to another embodiment of the invention, the different images may be provided to people located in various directions.

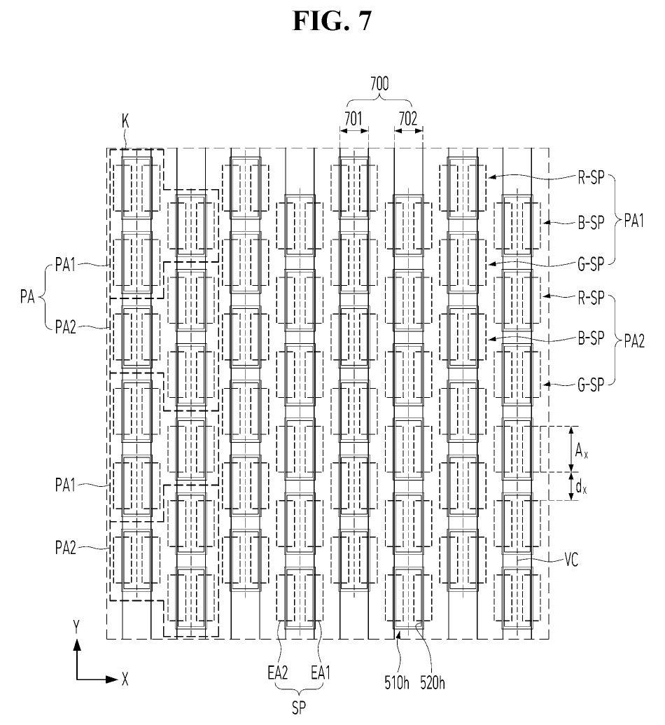

The display apparatus according to an embodiment of the invention is described such that a plane of each optical lens 700 has a bar shape extending in the second direction Y. However, in the display apparatus according to another embodiment of the invention, each of the optical lenses 700 may overlap with a plurality of sub-pixels SP disposed side-by-side in the second direction Y. For example, in the display apparatus according to another embodiment of the invention, the optical lenses 700 may extend in the second direction Y, as shown in FIG. 7. The optical lens 700 overlapping with at least one of the sub-pixels SP in each second pixel area PA2 may overlap with at least one of the sub-pixels SP in the first pixel area PA1 adjacent in the second direction Y. For example, the optical lenses 700 may include first lenses 701 and second lenses 702 repeatedly arranged in the first direction X, the red sub-pixel R-SP of each first pixel area PA1, the green sub-pixel G-SP of each first pixel area PA1, and the blue sub-pixel B-SP of each second pixel area PA2 may overlap with one of the first lenses 701, and the blue sub-pixel B-SP of each first pixel area PA1, the red sub-pixel R-SP of each second pixel area PA2, and the green sub-pixel G-SP of each second pixel area PA2 may overlap with one of the second lenses 702. Thus, in the display apparatus according to another embodiment of the invention, a process of forming the optical lenses 700 may be simplified. Therefore, in the display apparatus according to another embodiment of the invention, the process efficiency may be improved.

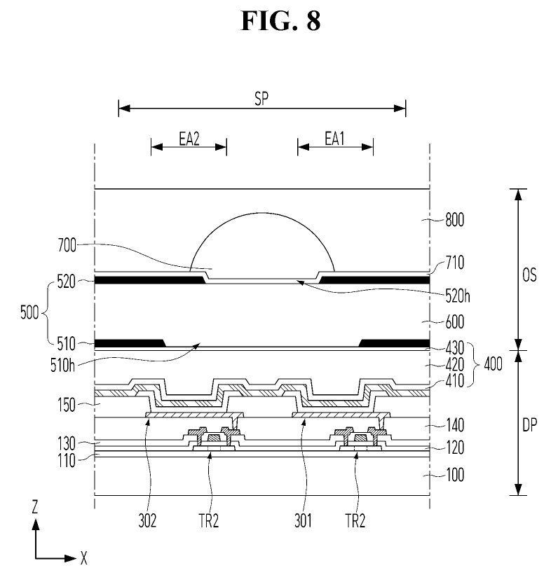

The display apparatus according to an embodiment of the invention is described such that a lower surface of each optical lens 700 toward the device substrate 100 may be in direct contact with the upper surface of the optical insulating layer 600 within the upper opening 520h of each sub-pixel SP. However, in the display apparatus according to another embodiment of the invention, at least one insulating layers may be disposed between the optical insulating layer 600 and the optical lenses 700. For example, in the display apparatus according to another embodiment of the invention, the optical structure OS may include a lens passivation layer 710 covering the upper barrier pattern 520, as shown in FIG. 8. The optical lens 700 of each sub-pixel SP may be disposed on the lens passivation layer 710.

The lens passivation layer 710 may include an insulating material. The lens passivation layer 710 may include a different material from the optical insulating layer 600. For example, the lens passivation layer 710 may be an inorganic insulating layer made of an inorganic insulating material. Thus, in the display apparatus according to another embodiment of the invention, diffusion of moisture and/or oxygen moving through the optical insulating layer 600 may be blocked by the lens passivation layer 710. For example, in the display apparatus according to another embodiment of the invention, moisture and/or oxygen moving through the optical insulating layer 600 cannot penetrate the optical lenses 700 by the lens passivation layer 710. Therefore, in the display apparatus according to another embodiment of the invention, deformation of the optical lenses 700 due to the penetration of moisture and/or oxygen may be reduced.

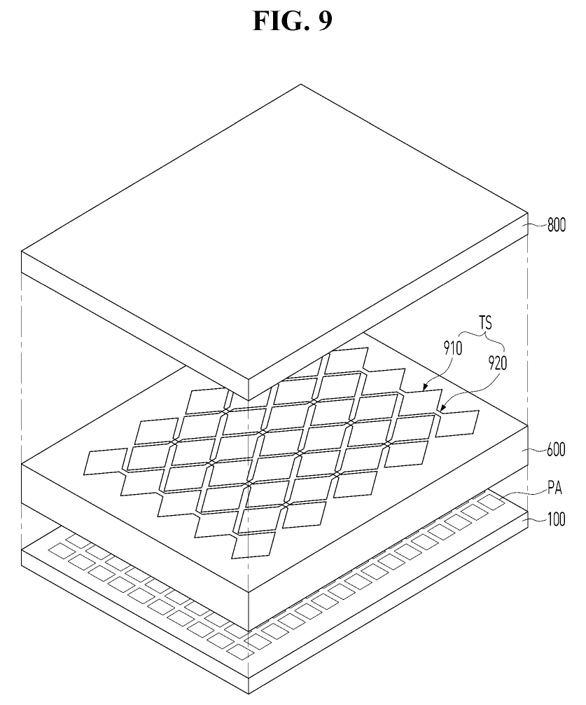

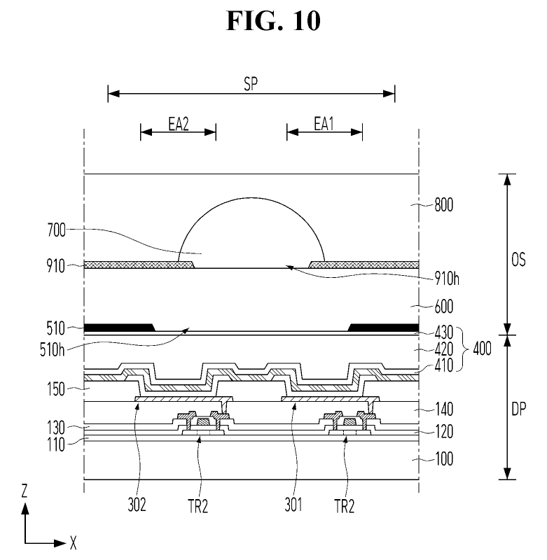

The display apparatus according to an embodiment of the invention is described such that the upper barrier pattern 520 includes a same material as the lower barrier pattern 510. However, in the display apparatus according to another embodiment of the invention, the upper barrier pattern 520 may include a different material from the lower barrier pattern 510. For example, in the display apparatus according to another embodiment of the invention, a touch sensor TS for sensing a touch of the user or a tool may be disposed between the optical insulating layer 600 and the lens planarization layer 800 of the optical structure OS, as shown in FIGS. 9 and 10.

The touch sensor TS may include touch electrodes 910 and bridge electrodes 920 connecting between the touch electrodes 910. The touch electrodes 910 and the bridge electrodes 920 may include a conductive material. The touch electrodes 910 and the bridge electrodes 920 may include a material capable of blocking light. For example, the touch electrodes 910 and the bridge electrodes 920 may include a metal. At least some of the bridge electrodes 920 may include a different material from the touch electrodes 910. For example, at least some of the bridge electrode 920 may be disposed on a different layer from the touch electrodes 910.

The touch electrodes 910 may be disposed between the optical insulating layer 600 and the lens planarization layer 800. For example, a lower surface of each touch electrode 910 toward the device substrate 100 may be in direct contact with the upper surface of the optical insulating layer 600, and an upper surface of each touch electrode 910 opposite to the device substrate 100 may be in direct contact with the lens planarization layer 800. The touch electrodes 910 may include touch openings 910hoverlapping with the lower openings 510h of the lower barrier pattern 610 and the optical lenses 700. For example, the light passing through the lower opening 510h of each sub-pixel SP may be emitted through one of the touch openings 910h. That is, in the display apparatus according to another embodiment of the invention, the touch electrodes 910 may function as the upper barrier pattern. Thus, in the display apparatus according to another embodiment of the invention, a process of forming the upper barrier pattern may be omitted by the touch sensor TS. Therefore, in the display apparatus according to another embodiment of the invention, the process efficiency may be improved.

The display apparatus according to embodiments of the invention, the image provided to the user disposed obliquely on the display panel through one of the emission areas of each sub-pixel cannot be recognized by people disposed in a different direction from the user, and the luminance of the light provided to the users by the emission areas of each sub-pixel may be improved. Thus, in the display apparatus according to embodiments of the invention, the quality of the image provided to the user disposed obliquely on the display panel may be improved, and the accidents due to gaze dispersion of the people located around the user may be prevented. Thereby, in the display apparatus according to embodiments of the invention, the low-power operation may be possible, and the power consumption may be reduced.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a display panel including a first pixel area and a second pixel area; and
optical lenses disposed on the display panel, each of the optical lenses having a semicircular cross-sectional shape in a first direction,
wherein:
sub-pixels configured to display different colors disposed in each of the first pixel area and the second pixel area;
each of the sub-pixels includes two emission areas disposed side-by-side in the first direction and overlapping with one of the optical lenses;
the second pixel area is disposed side-by-side with the first pixel area in a second direction perpendicular to the first direction; and
the arrangement of the sub-pixels in the second pixel area is symmetrical to the arrangement of the sub-pixels in the first pixel area.

2. The display apparatus according to claim 1, wherein the two emission areas in each sub-pixel have a planar shape of a bar extending in the second direction.

3. The display apparatus according to claim 1, wherein:
the sub-pixels include a first sub-pixel, a second sub-pixel disposed side-by-side with the first sub-pixel in the second direction, and a third sub-pixel spaced apart from the first sub-pixel and the second sub-pixel in the first direction; and
each of the emission areas in the third sub-pixel includes a region facing the emission areas of the first sub-pixel in the first direction and a region facing the emission areas of the second sub-pixel in the first direction.

4. The display apparatus according to claim 3, wherein:
each of the optical lenses extends in the second direction;
the emission areas of the third sub-pixel in the second pixel area overlap with the same optical lens as the emission areas of the first sub-pixel in the first pixel area and the emission areas of the second sub-pixel in the first pixel area; and
the emission areas of the first sub-pixel in the second pixel area and the emission areas of the second sub-pixel in the second pixel area overlap with the same optical lens as the emission areas of the third sub-pixel in the first pixel area.

5. The display apparatus according to claim 1, wherein the two emission areas disposed in each of the sub-pixels have the same size.

6. The display apparatus according to claim 5, wherein a distance between adjacent emission areas in the second direction is less than a length of each of the emission areas in the second direction.

7. The display apparatus according to claim 1, further comprising an upper barrier pattern disposed between the display panel and the optical lenses,
wherein the upper barrier pattern includes upper openings overlapping with the optical lenses.

8. The display apparatus according to claim 7, wherein a plane of each of the upper openings has a symmetrical shape with respect to a virtual center line passing through a lens center point of the corresponding optical lens in the second direction.

9. The display apparatus according to claim 7, further comprising a lower barrier pattern disposed between the display panel and the upper barrier pattern,
wherein the lower barrier pattern includes lower openings overlapping with the upper openings of the upper barrier pattern.

10. The display apparatus according to claim 9, wherein the lower barrier pattern includes a different material from the upper barrier pattern.

11. The display apparatus according to claim 9, wherein:
each of the upper openings has a smaller size than each optical lens; and
a size of each of the lower openings is larger than a size of each of the upper openings.

12. The display apparatus according to claim 1, wherein each of the two emission areas in each sub-pixel includes a region overlapping with one of the optical lenses and a region disposed outside the optical lenses.

13. The display apparatus according to claim 1, wherein the two emission areas in each sub-pixel display the same color.

14. The display apparatus according to claim 7, further comprising a lens passivation layer disposed below the optical lenses and covering the upper barrier pattern.

15. The display apparatus according to claim 1, further comprising a touch sensor including touch electrodes disposed between the display panel and the optical lenses,
wherein the touch electrodes include upper openings overlapping with the optical lenses.

16. The display apparatus according to claim 15, further comprising a barrier pattern disposed between the display panel and the touch electrodes,
wherein the barrier pattern includes lower openings overlapping with the upper openings of the touch electrodes.

17. The display apparatus according to claim 16, wherein:
each of the upper openings has a smaller size than each optical lens; and
a size of each of the lower openings is larger than a size of each of the upper openings.
